(19) United States
(12) Patent Application Publication
(10) Pub. No.: US 2021/0149102 A1
(43) Pub. Date: May 20, 2021

(54) LIGHT EMITTING KEYBOARD

(71) Applicant: CHICONY POWER TECHNOLOGY CO., LTD., New Taipei City (TW)

(72) Inventors: Hsuan-Wei HO, New Taipei City (TW); Yueh-Heng LEE, New Taipei City (TW)

(21) Appl. No.: 16/935,967

(22) Filed: Jul. 22, 2020

(30) Foreign Application Priority Data
Oct. 25, 2019 (TW) 108138706

(51) Int. Cl. F21V 8/00

(52) U.S. Cl. CPC G02B 6/0036; G02B 6/0076; G02B 6/0043

(57) ABSTRACT

The present disclosure discloses a light emitting keyboard, which includes a keyboard module and a backlight module. The backlight module includes a light emitting component, a light guide plate, and a light interference unit. The light guide plate receives the light from the light emitting component. The light guide plate has a top surface, a bottom surface, and a first designate area. The top surface faces the keyboard module, and the bottom surface is on the opposite side of the top surface. The first designate area corresponds to at least one of the keycaps of the keyboard module. The light interference unit is disposed on the light guide plate, and includes at least one light interfering set. The light interfering set guides part of the light in the light guide plate to the first designate area, and the light interfering set is one kind of periodic structures.

### BACKGROUND OF THE DISCLOSURE

### 1. Field of the Disclosure

The present disclosure relates to a light emitting keyboard, particularly to a light guide plate of a light emitting keyboard.

### 2. Description of the Related Art

With the rapid development of today's electronic technology and information industry, various electronic devices are developed toward a light, thin, and diversified trend. For example, computers, notebook computers, tablets, and smart phones have become indispensable electronic devices for modern people in daily life. In most cases, a user operates an electronic device using an input device such as a mouse or a keyboard, and the keyboard is most commonly used.

To clearly see symbols on each key in a low-light environment, a light source technology has been introduced into the keyboard for developing a light emitting keyboard with a backlight module. For the light emitting keyboard currently on the market, a backlight module is provided at the bottom of the keyboard module. The backlight module includes an optical structure such as a light guide plate and a light emitting component. The light emitting component is disposed on the light guide plate, such that light can be guided to the bottom of the entire keyboard by the light guide plate and the light is projected onto the back of the keycap of each key. The light is transmitted through the key face or the periphery of the key, allowing the user to see the symbol on the keycap.

Due to the high cost of the light emitting component and its circuit board, when designing the overall luminance of the light emitting keyboard, the configuration area of the light emitting component and its circuit board is minimized to achieve a cost reduction effect. However, the disadvantage of this design is that the light emitting component is concentrated in an area, and the screw hole for assembling affects the transmission of light in the light guide plate, which will easily cause the light field of the light emitting keyboard to be unevenly distributed and the light of some areas may be dark.

### SUMMARY

In view of above issues, it is a major objective of the present disclosure to provide a light emitting keyboard, wherein a light interference unit is disposed on a light guide plate. Through the meta-structure of the light interference unit, the problem of uneven distribution (dark area) of the light field can be solved.

To achieve the above objective, the present disclosure provides a light emitting keyboard, which includes a keyboard module and a backlight module. The keyboard module includes a plurality of keycaps. The backlight module is disposed below the keyboard module. The backlight module includes a light emitting component, a light guide plate, and a light interference unit. The light guide plate is disposed adjacent to the light emitting component, and receives the light from the light emitting component. The light guide plate has a top surface, a bottom surface, and a first designate area. The top surface faces the keyboard module, and the bottom surface is disposed on the opposite side of the top surface. The first designate area corresponds to at least one of the keycaps. The light interference unit is disposed on the light guide plate. The light interference unit includes at least one light interfering set. The light interfering set guides part of the light within the light guide plate to the first designate area, and the light interfering set is one kind of periodic structure.

According to an embodiment of the present disclosure, the light interfering set has a plurality of strips, and the strips are arranged parallel to each other. The optical path length between the two adjacent strips from the light emitted by the light emitting component is an integer multiple of the wavelength of the light emitted by the light emitting component.

According to an embodiment of the present disclosure, the light interference unit includes a first light interfering set. Each of the strips of the first light interfering set extends in a first extension direction. The first light interfering set guides the light emitted by the light emitting component to the first designate area in a first transmission direction. The first extension direction and the first transmission direction are both parallel to the top surface.

According to an embodiment of the present disclosure, the light interference unit includes a first light interfering set and a second light interfering set. Each of the strips of one of the first light interfering set extends in a first extension direction and guides the light emitted by the light emitting component to the first designate area in a first transmission direction. Each of the strips of the second light interfering set extends in a second extension direction, and guides the light emitted by the light emitting component to the first designate area in a second transmission direction. The first extension direction, the first transmission direction, the second extension direction, and the second transmission direction are all parallel to the top surface. The first extension direction is different from the second extension direction.

According to an embodiment of the present disclosure, the light guide plate further includes a second designate area. The second designate area corresponds to at least the other one of the keycaps. The light interference unit includes a first light interfering set and a second interfering set. Each of the strips of the first light interfering set extends in a first extension direction, and guides the light emitted by the light emitting component to the first designate area in a first transmission direction. Each of strips of the second light interfering set extends in a second extension direction, and guides the light emitted by the light emitting component to the second designate area in a second transmission direction. The first extension direction, the first transmission direction, the second extension direction, and the second transmission direction are all parallel to the top surface. The first extension direction is different from the second extension direction.

According to an embodiment of the present disclosure, the spacing distance between any two adjacent strips is an integer multiple of the wavelength of the light emitted by the light emitting component.

According to an embodiment of the present disclosure, the light guide plate further includes a second designate area. The second designate area corresponds to at least the other one of the keycaps. Each of the strips of the light interfering set extends in a third extension direction. The light interfering set guides the light emitted by the light emitting component to a first designate area and a second designate area in a third transmission direction and a fourth transmission direction. The third extension direction, the third transmission direction, and the fourth transmission direction are all parallel to the top surface.

According to an embodiment of the present disclosure, the spacing distance between any two adjacent strips is a half integer multiple of the wavelength of the light emitted by the light emitting component.

According to an embodiment of the present disclosure, the light interference unit is disposed on the top surface or the bottom surface of the light guide plate. The backlight module further includes a luminous dot unit that is disposed on the bottom surface of the light guide plate. The luminous dot unit includes a plurality of luminous dots. The position of the luminous dots corresponds to the position of the keycaps, and the luminous dots guide the light to the keycaps.

According to an embodiment of the present disclosure, the position of the light interfering set corresponds to the position of the luminous dots.

According to an embodiment of the present disclosure, the position of the light interfering set corresponds to the position between the two adjacent luminous dots.

According to an embodiment of the present disclosure, the position of the light interfering set corresponds to the position of the keycaps. The light interfering set guides part of the light from the light emitting component to the keycaps and guides the other part of the light to the first designate area in a first transmission direction.

According to an embodiment of the present disclosure, each of the strips is a cylinder or is arranged by a plurality of dots on the top surface or the bottom surface. When each of the strips is a cylinder, the cylinder protrudes from the top surface or the bottom surface and has a ridge or a curved surface. When each of the strips is arranged by the dots on the top surface or the bottom surface, each dot is a bump or a pit.

According to an embodiment of the present disclosure, each of the strips of the light interfering set is a cylinder that protrudes from the top surface of the light guide plate. The backlight module further includes an auxiliary light guide plate on the top surface, and an auxiliary light interference unit on the auxiliary light guide plate. The auxiliary light interference unit includes at least one auxiliary light interfering set. The auxiliary light interfering set has a plurality of auxiliary strips which are a plurality of auxiliary cylinders. The auxiliary cylinder protrudes from a bottom surface of the auxiliary light guide plate and is interleaved with the strips of the light interfering set.

As above, according to the light emitting keyboard of the present disclosure, the backlight module includes a light emitting component, a light guide plate, and a light interference unit. The light interference unit is disposed on the light guide plate and includes at least one light interfering set. The light interfering set is one kind of periodic structure that can guide some of the light within the light guide plate to a dark area (e.g. the first designate area and/or the second designate area) to enhance the luminance of the area. Therefore, the effect of avoiding the uneven distribution of the light field of the light emitting keyboard can be achieved by selecting the aspect and configuration of the light interfering set.

### BRIEF DESCRIPTION OF THE DRAWINGS

FIG. 1 is a perspective exploded view of a light emitting keyboard in a first embodiment of the present disclosure;

FIG. 2 is a top view of the light emitting component and the area A on the light guide plate shown in FIG. 1;

FIG. 3 is a partial cross-sectional view of the light emitting component and the light guide plate shown in FIG. 1;

FIG. 4 is a top view of one of the light interfering sets and its adjacent luminous dots shown in FIG. 2;

FIG. 5 is a partial top view of a light emitting component, a light guide plate, a light interference unit and a luminous dot unit in a second embodiment of the present disclosure;

FIG. 6 is a partial top view of a light emitting component, a light guide plate, a light interference unit and a luminous dot unit in a third embodiment of the present disclosure;

FIG. 7 is a partial top view of a light emitting component, a light guide plate, a light interference unit and a luminous dot unit in a fourth embodiment of the present disclosure;

FIG. 8 is a partial top view of a light guide plate, a light interference unit and a luminous dot unit in a fifth embodiment of the present disclosure;

FIG. 9 is a partial top view of a light emitting component, a light guide plate, a light interference unit and a luminous dot unit in a sixth embodiment of the present disclosure; and

FIG. 10 is a partial cross-sectional view of a backlight module in a seventh embodiment of the present disclosure.

### DETAILED DESCRIPTION OF THE PREFERRED EMBODIMENT

Hereafter, the technical content of the present disclosure will be better understood with reference to preferred embodiments.

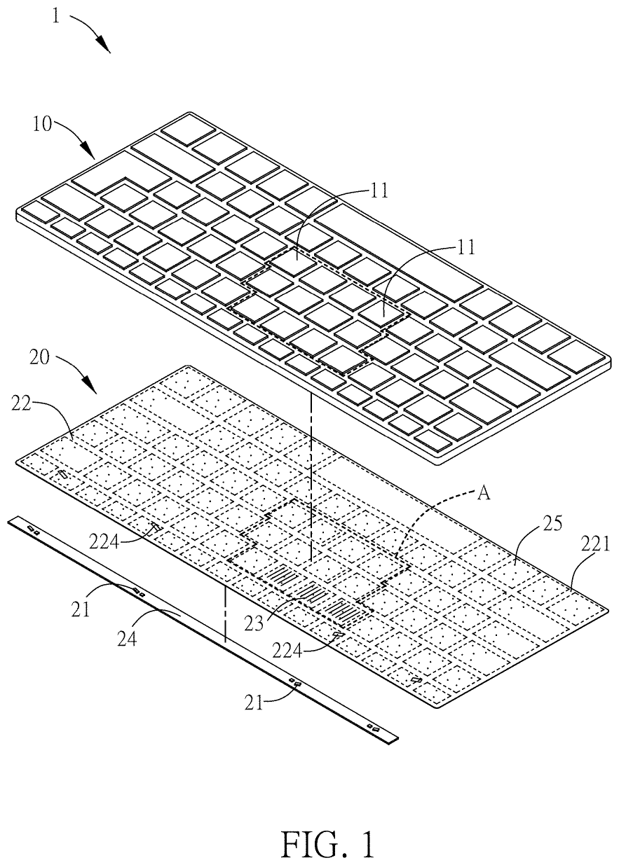

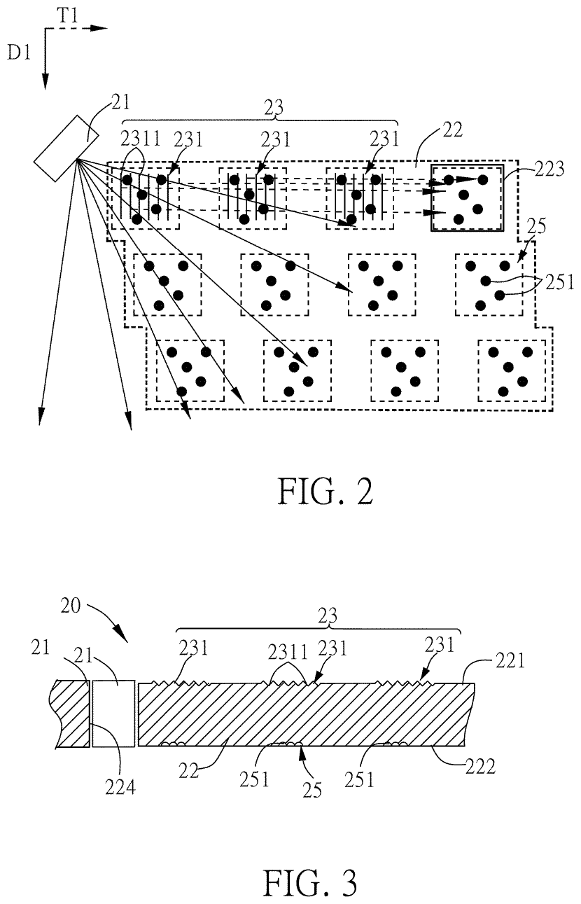

FIG. 1 is a perspective exploded view of a light emitting keyboard in a first embodiment of the present disclosure. FIG. 2 is a top view of the light emitting component and the area A on the light guide plate shown in FIG. 1. Please refer to both FIG. 1 and FIG. 2. In the present embodiment, a light emitting keyboard 1 includes a keyboard module 10 and a backlight module 20. The keyboard module 10 includes a plurality of keycaps 11. The backlight module 20 is disposed below the keyboard module 10, that is, on the opposite side of the keycaps 11. The backlight module 20 includes at least a light emitting component 21, a light guide plate 22 and a light interference unit 23. In the present embodiment, the light guide plate 22 has a top surface 221, a bottom surface 222 (see FIG. 3), a first designate area 223 (as shown in FIG. 2) and a plurality of slots 224. The top surface 221 faces the keyboard module 10, the bottom surface 222 is disposed on the opposite side of the top surface 221, and the slots 224 pass through the top surface 221 and the bottom surface 222.

The light guide plate 22 is disposed adjacent to the light emitting component 21, and receives the light from the light emitting component 21. Specifically, the light emitting component 21 is disposed on a circuit board 24. The circuit board 24 is disposed on the bottom surface 222 of the light guide plate 22, and the light emitting component 21 is correspondingly accommodated in the slots 224. The light emitted by the light emitting component 21 can be incident on the light guide plate 22 by the slot 224. That is, the light emitted by the light emitting component 21 will be received by the light guide plate 22.

It should be noted that the light emitting component 21 of the embodiment is mainly disposed on one side of the light guide plate 22. This configuration is usually easy to make the light field distribution of the light emitting keyboard uneven (as explained in the prior art described above). The designate areas in this embodiment (the first designate area 223 and the second designate area of the third, fourth, and fifth embodiments as described hereinafter, wherein the first designate area 223 is illustrated as an example in the first embodiment hereinafter) refers to the dark area caused by the uneven distribution of the light field in the prior art. Further, this embodiment defines that the first designate area 223 corresponds to at least one keycap 11. Preferably, a specified area (e.g. the first designate area 223) can accurately correspond to the position of a keycap 11, but the present disclosure is not limited to thereto. It should be noted that, in order to clarify the technical features, in each of the figures, the position of each keycap 11 on the light guide plate 22 is indicated by a dashed line.

The light interference unit 23 is disposed on the light guide plate 22, and the light interference unit 23 can be directly formed on the top surface 221 or the bottom surface 222 of the light guide plate 22. In the present embodiment, the light interference unit 23 is formed on the top surface 221 of the light guide plate 22, as shown in FIG. 3. FIG. 3 is a partial cross-sectional view of a light emitting component and a light guide plate shown in FIG. 1. The light interference unit 23 includes at least one light interfering set 231, and the light interference unit 23 includes a plurality of light interfering sets 231 as an example. Each of the light interfering sets 231 includes a plurality of strips 2311. In the present embodiment, each of the strips 2311 is a cylinder that protrudes from the top surface 221 (in other embodiments, may also protrude from the bottom surface 222) and has a ridge (triangular) or a curved surface (half cylindrical type). FIG. 3 is an example of the strips 2311 with ridge lines.

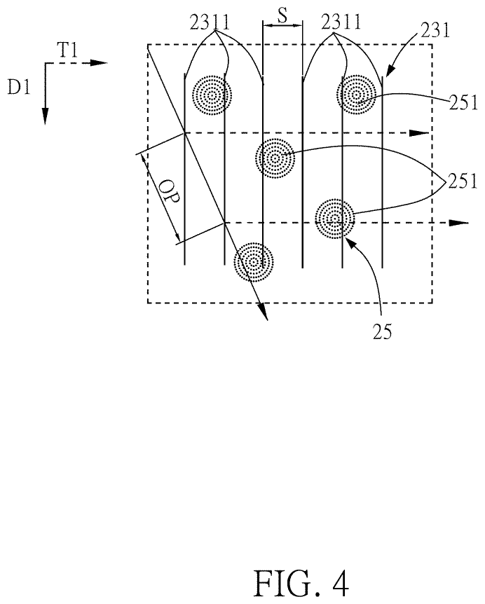

In the present embodiment, each of the light interfering sets 231 is one kind of periodic structure. Thus, the light interfering sets 231 can guide part of the light in the light guide plate 22 (the light passing through the light interfering sets 231) to the first designate area 223, thereby increasing the luminance of the first designate area 223 (the dark area). FIG. 4 is a top view of one of the light interfering sets shown in FIG. 2 and its adjacent luminous dots (described later). Please refer to FIG. 1 to FIG. 4. Specifically, each of the strips 2311 of one of the light interfering sets 231 is arranged parallel to each other, and any two adjacent of the strips 2311 have the same spacing distance S to form a periodic structure, as shown in FIG. 4. In the first embodiment, the optical path length (OP) between the two adjacent strips 2311 from the light emitted by the light emitting component 21 is set to an integer multiple of the wavelength of the light emitted by the light emitting component 21. Since the light wave originally traveling in different directions will physically reflect between the two adjacent strips 2311, destructive interference and constructive interference, after the light passes through the light interfering sets 231, collimated light is transmitted and concentrated in a specific direction (the first transmission direction T1, the second transmission direction T2, the third transmission direction T3 and the fourth transmission direction T4 as described hereinafter) toward the target of the designate area (dark area).

Moreover, in order to limit the optical path length (OP) between the two adjacent strips 2311 to generate collimated light, it can be achieved by designing the spacing distance S between the two adjacent strips 2311. For example, the spacing distance S between the two adjacent strips 2311 may be an integer multiple or a half-integer multiple of the wavelength of the light emitted by the light emitting component 21. In the first embodiment, the spacing distance S between the two adjacent strips 2311 is an integer multiple of the wavelength of the light emitted by the light emitting component 21 is used as an example for illustration.

Accordingly, since the spacing distance S between the two adjacent strips 2311 is an integer multiple of the wavelength of the light, the light interfering sets 231 can guide the light to a direction perpendicular to the strips 2311 (the direction in which the light wave constructively interferes, i.e. the first transmission direction T1), as shown in FIG. 2 and FIG. 4. When designing the arrangement position of the light interfering sets 231 and strips 2311 thereof, firstly, the first transmission direction Ti may be set toward the first designate area 223 (the dark area). Then, the direction perpendicular to the first transmission direction T1 is set to be first extension direction D1. Further, each of the strips 2311 of the light interfering sets 231 extends in the first extension direction D1 and is arranged parallel to each other, such that the light interfering sets 231 can guide the light emitted by the light emitting component 21 to the first designate area 223 in the first transmission direction T1. Thus, the luminance of the first designate area 223 (the dark area) is increased to reduce the uneven distribution of the luminance of the light emitting keyboard 1. It should be noted that the first extension direction D1 and the first transmission direction T1 are parallel to the top surface 221 of the light guide plate 22. That is, most of the light passes through the light interfering sets 231 and continues to be transmitted in the light guide plate 22.

Reffering to FIG. 1 to FIG. 4, the backlight module 20 further includes a luminous dot unit 25. In the first embodiment, the light interference unit 23 is disposed on the top surface 221 of the light guide plate 22, and the luminous dot unit 25 is disposed on the bottom surface 222 of the light guide plate 22. The luminous dot unit 25 includes a plurality of luminous dots 251, and the position of the luminous dots 251 corresponds to the keycaps 11. When the light emitted by the light emitting component 21 contacts the luminous dots 251 in the light guide plate 22, the light is guided to the keycaps 11 by the luminous dots 251. In other words, the luminous dots 251 can guide the light in the light guide plate 22 to emit from the light guide plate 22 to the keycaps 11, thereby achieving the effect of illuminating the keycaps 11. It should be noted that the light interference unit 23 of the present embodiment guides the light in the light guide plate 22 to a specific direction inside the light guide plate 22. The luminous dot unit 25 guides the light in the light guide plate 22 toward the keycaps 11 out of the light guide plate 22.

In other embodiments, the light interfering sets 231 can have other different configurations as long as the light can be guided to the dark area. In addition, the light interference unit 23 can also have the effect of the luminous dot unit 25 (that is, simultaneously directing the light to the keycaps 11 and the dark area), which are further described in different embodiments hereinafter.

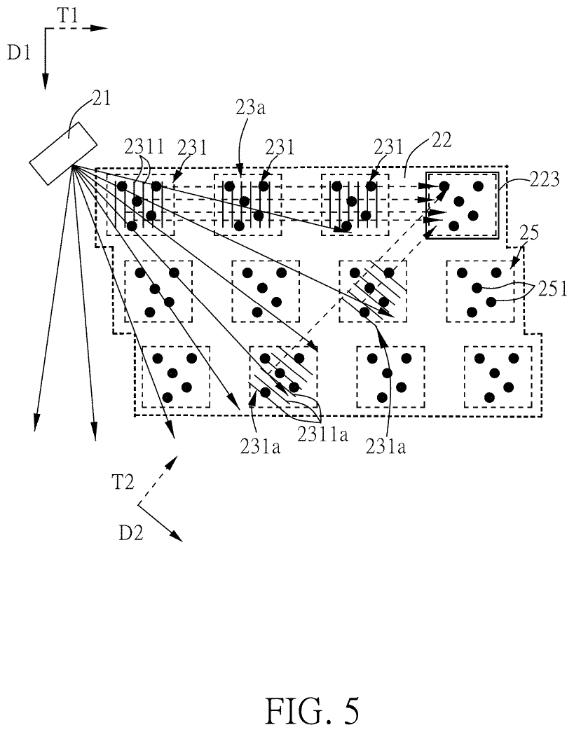

FIG. 5 is a partial top view of a light emitting component, a light guide plate, a light interference unit and a luminous dot unit in a second embodiment of the present disclosure. Referring to FIG. 5, in the present embodiment, the light interference unit 23a includes two different arrangements of light interfering sets 231, 231a. The light interfering sets 231 are configured in the same manner as the first embodiment, and thus the same reference numerals are used (other identical components also follow the same reference numerals). That is, each of the strips 2311 of the light interfering sets 231 extends in the first extension direction D1, and the light emitted by the light emitting component 21 can be guided to the first designate area 223 in the first transmission direction T1. Each of the strips 2311a of the other one of the light interfering sets 231a extends in a second extension direction D2, and the light emitted by the light emitting component 21 is guided to the first designate area 223 in a second transmission direction T2. The first extension direction D1, the first transmission direction T1, the second extension direction D2 and the second transmission direction T2 are all parallel to the top surface 221.

Specifically, the first transmission direction T1 is perpendicular to two of the sides (specified by the developer) of the first designate area 223 in FIG. 5. The second transmission direction T2 is set to be toward one corner of the first designate area 223 in FIG. 5. Similarly, the direction perpendicular to the second transmission direction T2 (i.e. the direction in which the constructive interference is predetermined) is set to be second extension direction D2. As shown in FIG. 5, the first extension direction D1 is different from the second extension direction D2. Specifically, the light interfering sets 231 can guide the light to the first designate area 223 in the first transmission direction T1. The light interfering sets 231a can guide the light to the first designate area 223 in the second transmission direction T2, thereby further increasing the luminance of the first designate area 223 (the dark area).

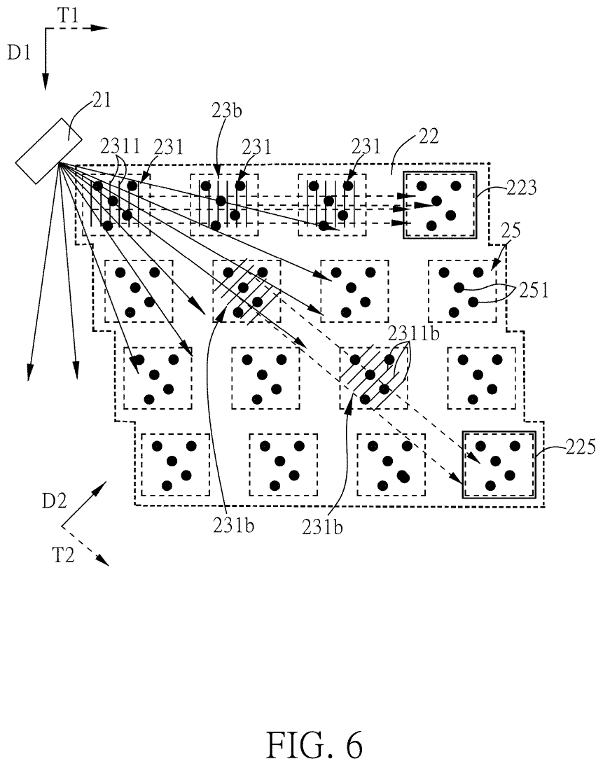

FIG. 6 is a partial top view of a light emitting component, a light guide plate, a light interference unit and a luminous dot unit in a third embodiment of the present disclosure. Please refer to FIG. 1 and FIG. 6. The second embodiment is applied to the case that the configuration of the light interference unit 23b if the case that the light emitting keyboard has more than two dark areas (i.e. the first designate area 223 and the second designate area 225) needs improvement. Specifically, the light guide plate 22 has a first designate area 223 and a second designate area 225, respectively corresponding to at least two keycaps 11. In the present embodiment, the light interference unit 23b also includes two different configurations of the light interfering sets 231, 231b. One of the light interfering sets 231 is configured in the same manner as the first embodiment, and thus the same reference numerals are used (other identical components also follow the same reference numerals). The first extension direction D1 is parallel to two of the sides of the first designate area 223 in FIG. 6. Each of the strips 2311 of the light interfering sets 231 extends in the first extension direction D1 to guide the light emitted by the light emitting component 21 to the first designate area 223 in the first transmission direction T1 (perpendicular to each of the strips 2311) to increase the luminance of the first designate area 223. Further, each of the strips 2311b of the other light interfering sets 231b extends in a second extension direction D2, where the first extension direction D1 is different from the second extension direction D2. A second transmission direction T2 is set to be toward one corner of the second designate area 225. The light interfering sets 231b an guide the light emitted by the light emitting component 21 to the second designate area 225 in the second transmission direction T2 (perpendicular to each of the strips 2311b). Accordingly, the luminance of the second designate area 225 is improved to achieve the light field distribution and uniform luminance of the light emitting keyboard 1. Similarly, the first extension direction D1, the first transmission direction T1, the second extension direction D2 and the second transmission direction T2 are all parallel to the top surface 221.

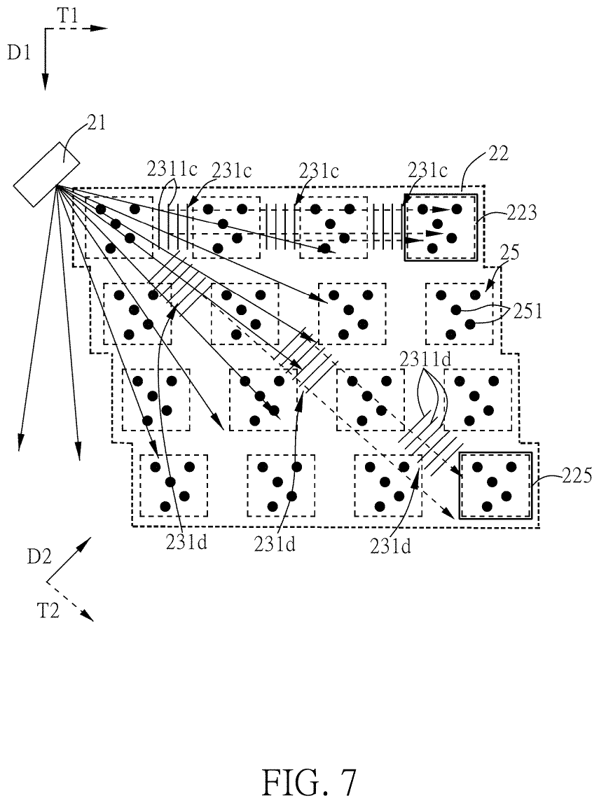

FIG. 7 is a partial top view of a light emitting component, a light guide plate, a light interference unit and a luminous dot unit in a fourth embodiment of the present disclosure. Please refer to FIG. 1 and FIG. 7. In the first to third embodiment, all of the light interfering sets 231, 231a, 231b and all of the luminous dots 251 correspond to the position of the keycaps 11. That is, in the first to third embodiment, the position of the light interfering sets 231, 231a, 231b corresponds to the position of the luminous dots 251 (since the luminous dots 251 correspond to the keycaps 11). However, in the fourth embodiment, the position of the light interfering sets 231c, 231d corresponds to the position between the two adjacent luminous dots 251. In other words, the position of the light interfering sets 231c, 231d in the present embodiment corresponds to the position between the two adjacent keycaps 11. Similarly, each of the strips 2311c of the light interfering sets 231c extends in the first extension direction D1 to guide the light emitted by the light emitting component 21 to the first designate area 223 in the first transmission direction T1, thereby increasing the luminance of the first designate area 223. Also, each of the strips 2311d of the light interfering sets 231d extends in the second extension direction D2 to guide the light emitted by the light emitting component 21 to the second designate area 225 in the second transmission direction T2. Accordingly, the luminance of the second designate area 225 is improved to achieve the light field distribution and uniform luminance of the light emitting keyboard 1. Similarly, the first extension direction D1, the first transmission direction T1, the second extension direction D2 and the second transmission direction T2 are all parallel to the top surface 221.

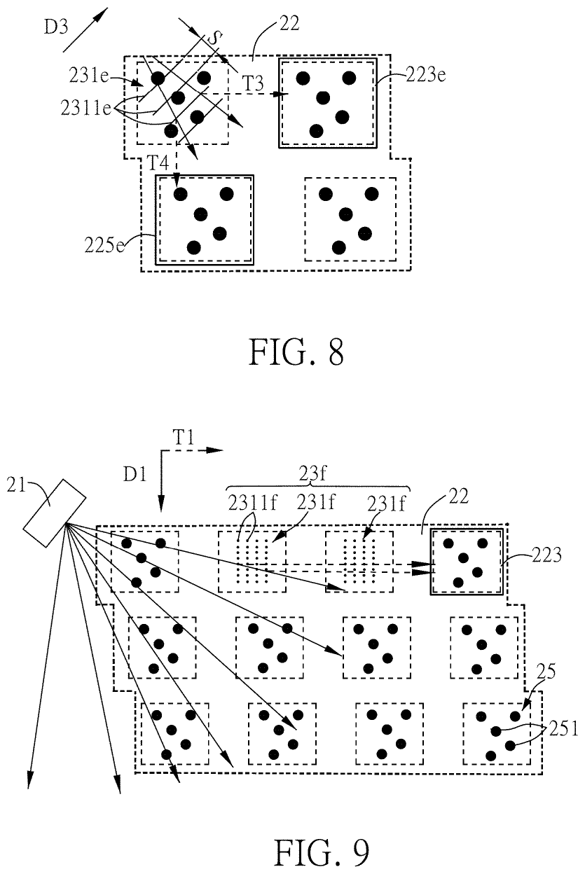

FIG. 8 is a partial top view of a light guide plate, a light interference unit and a luminous dot unit in a fifth embodiment of the present disclosure. Please refer to FIG. 1 and FIG. 8. In the first to fourth embodiment, the spacing distance S between the two adjacent strips 2311 (2311a, 2311b, 2311c, 2311d) is an integer multiple of the wavelength of the light emitted by the light emitting component 21. Therefore, the light passing through the light interfering sets 231 (231a, 231b, 231c, 231d) will only constructively interfere in one direction (that is, perpendicular to the strips). However, in the fifth embodiment, the spacing distance S between any of the two adjacent strips 2311e is a half integral multiple of the wavelength of the light emitted by the light emitting component 21. Therefore, the light passing through the light interfering set 231e will destructively interfere in the direction perpendicular to the strips 2311e, and will further be transmitted forward in the left and right sides of the light interfering set 231e in FIG. 8 in the third transmission direction T3 and the fourth transmission direction T4 (i.e. the direction in which the constructive interference occurs). Specifically, the embodiment can be applied to the case if there are two dark areas on the light emitting keyboard (e.g. the first designate area 223e and the second designate area 225e in FIG. 8) needs to be improved, a light splitting structure such as the light interfering set 231e can be disposed near the dark area to increase the luminance. Similarly, the first designate area 223e corresponds to one of the keycaps 11 and the second designate area 225e corresponds to other one of the keycaps 11.

Each of the strips 2311e of the light interfering set 231e of the present embodiment extends in a third extension direction D3, such that the light from the light source forms two collimated rays in the third transmission direction T3 and the fourth transmission direction T4, respectively. Specifically, an angle between the third transmission direction T3 and one of the strips 2311e (or the third extension direction D3) is 45 degrees, and an angle between the fourth transmission direction T4 and one of the strips 2311e (or the third extension direction D3) is 45 degrees, such that the third transmission direction T3 and the fourth transmission direction T4 are respectively guided to the left front and right front sides of the light interfering set 231e in FIG. 8. Therefore, the light interfering set 231e can respectively guide the light emitted by the light emitting component 21 in the third transmission direction T3 and the fourth transmission direction T4 to the first designate area 223e and the second designate area 225e on the adjacent sides of the light interfering set 231e. In the present embodiment, the third extension direction D3, the third transmission direction T3 and the fourth transmission direction are all parallel to the top surface 221 of the light guide plate 22. In other words, after passing through the light interfering set 231e, most of the light is still transmitted continuously in the light guide plate 22.

FIG. 9 is a partial top view of a light emitting component, a light guide plate, a light interference unit and a luminous dot unit in a sixth embodiment of the present disclosure. Please refer to FIG. 1 and FIG. 9. In the first to fifth embodiment, the light is mainly guided to the keycaps 11 by the luminous dot unit 25. In the sixth embodiment, however, the light is guided to the keycaps 11 by the luminous dots 251 of the luminous dot unit 25, and can also be guided to the keycaps 11 by the light interfering sets 231f of the light interference unit 23f. Specifically, the position of the light interfering sets 231f in the present embodiment correspond to the position of the keycaps 11, and the strips 2311f are arranged by a plurality of dots on the top surface 221 or the bottom surface 222 of the light guide plate 22; wherein, the dot may be a bump or a pit to achieve the effect of directing the light in the light guide plate 22 to the top surface 221 of the light guide plate 22 and directing it to the keycaps 11. In other words, the light interfering sets 231f not only guides part of light emitted by the light emitting component 21 to the first designate area 223 in the first transmission direction T1, but guides the other part of light to the keycaps 11 to function as a luminous dots 251. Therefore, the light interfering sets 231f have a dual effect.

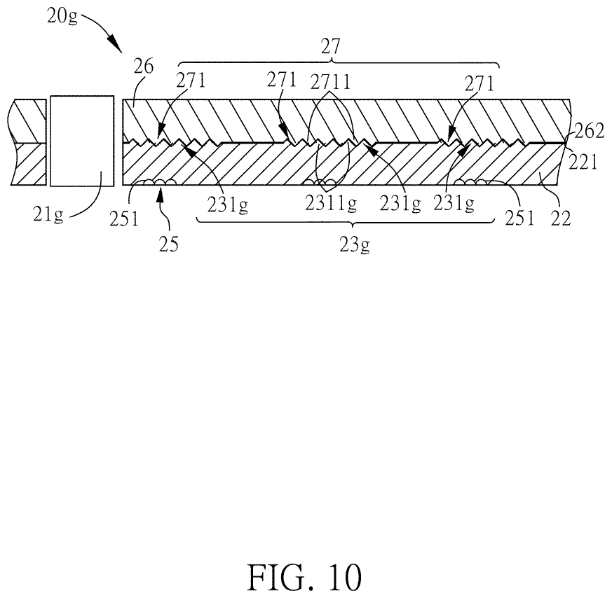

FIG. 10 is a partial cross-sectional view of a backlight module in a seventh embodiment of the present disclosure. Please refer to FIG. 10. Each of the strips 2311g of the light interfering sets 231g in the present embodiment is a cylinder and protrudes from the top surface 221 of the light guide plate 22. Further, the backlight module 20g further includes an auxiliary light guide plate 26 and an auxiliary light interference unit 27. The auxiliary light interference unit 27 is disposed on a bottom surface 262 of the auxiliary light guide plate 26. Specifically, the auxiliary light interference unit 27 includes at least one auxiliary light interfering sets 271. The auxiliary light interfering sets 271 includes a plurality of auxiliary strips 2711 that are a plurality of auxiliary cylinders. The auxiliary cylinder protrudes from the bottom surface 262 of the auxiliary light guide plate 26. The auxiliary light guide plate 26 is disposed on the top surface 221 of the light guide plate 22, such that the auxiliary strips 2711 (auxiliary cylinders) are interleaved with the strips 2311g (cylinders) of the light interfering sets 231g. Preferably, the light emitting component 21g is correspondingly disposed at the junction of the top surface 221 of the light guide plate 22 and the bottom surface 262 of the auxiliary light guide plate 26. As far as possible, most of the light is directly passed through the strips 2311g and the auxiliary strips 2711 to greatly increase the light collimation effect and concentrate the light strongly.

As above, according to the light emitting keyboard of the present disclosure, the backlight module includes a light emitting component, a light guide plate, and a light interference unit. The light interference unit is disposed on the light guide plate, and includes at least one light interfering set. The light interfering set is a periodic structure that guides some of the light within the light guide plate to a dark area (e.g. the first designate area and/or the second designate area) to enhance the luminance of the area. Therefore, the effect of avoiding the uneven distribution of the light field of the light emitting keyboard can be achieved by selecting the aspect and configuration of the light interfering set.

It should be noted that the embodiments of the present disclosure described above are only illustrative. All without departing from the scope of the disclosure are defined solely by the appended claims.

What is claimed is:

1. A light emitting keyboard, comprising:
a keyboard module, comprising a plurality of keycaps; and
a backlight module, disposed below the keyboard module, the backlight module comprising:
a light emitting component;
a light guide plate, which is disposed adjacent to the light emitting component, and receives the light from the light emitting component, the light guide plate having a top surface, a bottom surface and a first designate area, the top surface facing the keyboard module, the bottom surface being disposed on the opposite side of the top surface, and the first designate area corresponding to at least one of the keycaps; and
a light interference unit, which is disposed on the light guide plate, and comprises at least one light interfering set, said at least one light interfering set guides part of the light within the light guide plate to the first designate area, said at least one light interfering set being one kind of periodic structure.

2. The light emitting keyboard as claimed in claim 1, wherein said at least one light interfering set has a plurality of strips arranged parallel to each other, and the optical path length (OP) between the two adjacent strips from the light emitted by the light emitting component is an integer multiple of the wavelength of the light emitted by the light emitting component.

3. The light emitting keyboard as claimed in claim 2, wherein the light interference unit comprises a first light interfering set, each of the strips of the first light interfering set extends in a first extension direction, the first light interfering set guides the light emitted by the light emitting component in a first transmission direction to the first designate area, and the first extension direction and the first transmission direction are both parallel to the top surface.

4. The light emitting keyboard as claimed in claim 2, wherein the light interference unit includes a first light interfering set and a second light interfering set, each of the strips of the first light interfering set extends in a first extension direction, and guides the light emitted by the light emitting component in a first transmission direction to the first designate area, and each of the strips of the second light interfering set extends in a second extension direction, and guides the light emitted by the light emitting component in a second transmission direction to the first designate area, wherein the first extension direction and the first transmission direction, the second extension direction and the second transmission direction are all parallel to the top surface, and the first extension direction is different from the second extension direction.

5. The light emitting keyboard as claimed in claim 2, wherein the light guide plate further comprising a second designate area, the second designate area corresponds to at least the other one of the keycaps, the light interference unit including a first light interfering set and a second light interfering set, each of the strips of the first light interfering set extends in a first extension direction, and guides the light emitted by the light emitting component to the first designate area in a first transmission direction, each of the strips of the second light interfering set extends in a second extension direction, and guides the light emitted by the light emitting component to the second designate area in a second transmission direction, the first extension direction, the first transmission direction, the second extension direction and the second transmission direction are all parallel to the top surface, and the first extension direction is different from the second extension direction.

6. The light emitting keyboard as claimed in claim 3, wherein the spacing distance between any two adjacent strips is an integer multiple of the wavelength of the light emitted by the light emitting component.

7. The light emitting keyboard as claimed in claim 4, wherein the spacing distance between any two adjacent strips is an integer multiple of the wavelength of the light emitted by the light emitting component.

8. The light emitting keyboard as claimed in claim 5, wherein the spacing distance between any two adjacent strips is an integer multiple of the wavelength of the light emitted by the light emitting component.

9. The light emitting keyboard as claimed in claim 2, wherein the light guide plate further includes a second designate area, the second designate area corresponds to at least the other one of the keycaps, each of strips of said at least one light interfering set extends in a third extension direction, said at least one light interfering set guides the light emitted by the light emitting component to the first designate area and the second designate area in a third transmission direction and a fourth transmission direction, and the third extension direction, the third transmission direction and the fourth transmission direction are all parallel to the top surface.

10. The light emitting keyboard as claimed in claim 9, wherein the spacing distance between any two adjacent strips is a half integer multiple of the wavelength of the light emitted by the light emitting component.

11. The light emitting keyboard as claimed in claim 1, wherein the light interference unit is disposed on the top surface or the bottom surface of the light guide plate, the backlight module further comprises a luminous dot unit that is disposed on the bottom surface of the light guide plate, the luminous dot unit comprises a plurality of luminous dots whose position corresponding to that of the keycaps, and the luminous dots guide light to the keycaps.

12. The light emitting keyboard as claimed in claim 11, wherein the position of said at least one light interfering set corresponds to the position of the luminous dots.

13. The light emitting keyboard as claimed in claim 11, wherein the position of said at least one light interfering set corresponds to the position between two adjacent luminous dots.

14. The light emitting keyboard as claimed in claim 11, wherein the position of said at least one light interfering set corresponds to the position of the keycaps, and said at least one light interfering set guides part of the light from the light emitting component to the keycaps and guides the other part of the light to the first designate area in a first transmission direction.

15. The light emitting keyboard as claimed in claim 2, wherein each of the strips is a cylinder or is arranged by a plurality of dots on the top surface or the bottom surface, when each of the strips is the cylinder, the cylinder protrudes from the top surface or the bottom surface and has a ridge or a curved surface, and when each of the strips is arranged by the dots on the top surface or the bottom surface, each of the dots is a bump or a pit.

16. The light emitting keyboard as claimed in claim 15, wherein each of the strips of said at least one light interfering set is a cylinder that protrudes from the top surface of the light guide plate, the backlight module further comprises an auxiliary light guide plate disposed on the top surface, and an auxiliary light interference unit disposed on the auxiliary light guide plate, the auxiliary light interference unit includes at least one auxiliary light interfering set that has a plurality of auxiliary strips, and the auxiliary strips are respectively a plurality of auxiliary cylinders protruding from a bottom surface of the auxiliary light guide plate and interleaved with the strips of said at least one light interfering set.
